(19) United States
(12) Patent Application Publication
(10) Pub. No.: US 2007/0029677 A1
(43) Pub. Date: Feb. 8, 2007

(54) Interconnection structure

(75) Inventors: Takao Kamoshima, Hyogo (JP); Yasuhisa Fujii, Hyogo (JP); Takeshi Masamitsu, Hyogo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP., TOKYO (JP)

(21) Appl. No.: 11/488,634

(22) Filed: Jul. 19, 2006

Related U.S. Application Data
(62) Division of application No. 10/657,094, filed on Sep. 9, 2003, now abandoned.

(30) Foreign Application Priority Data
Mar. 5, 2003 (JP) 2003-058384

(51) Int. Cl. H01L 23/48

(52) U.S. Cl. 257/762

(57) ABSTRACT

An interconnection structure includes a lower interconnection layer formed on a substrate and composed of a copper layer, an interlayer insulating layer formed on the lower interconnection layer and having a via reaching the lower interconnection layer, an upper interconnection layer electrically connected to the lower interconnection layer through the via, and composed of a copper layer formed in the interlayer insulating layer, and a barrier metal layer formed between the upper interconnection layer and the interlayer insulating layer. The barrier metal layer has an opening in a bottom portion of the via, and through that opening, the upper interconnection layer comes in direct contact with the lower interconnection layer in the bottom portion of the via. Thus, an interconnection structure suppressing concentration of voids in an interconnection under a via due to stress migration can be attained.

### BACKGROUND OF THE INVENTION

1. Field of the Invention

The present invention relates to an interconnection structure, and more particularly to an interconnection structure for an electronic device such as a semiconductor device or a liquid crystal device.

2. Description of the Background Art

For a metal interconnection in an integrated circuit in a conventional semiconductor device, an aluminum (Al) alloy has mainly been employed. Meanwhile, for a state-of-the-art device, a copper (Cu) interconnection with lower resistance and excellent electromigration characteristic is employed. A semiconductor device with such a Cu interconnection is disclosed, for example, in Japanese Patent Laying-Open No. 2001-156073, and E. T. Ogawa et al., “Stress-Induced Voiding Under Vias Connected To Wide Cu Metal Leads” IEEE-02CH37320 40th Annual International Reliability Physics Symposium, Dallas, Tex., 2002, pp.312-321.

A manufacturing flow of the semiconductor device with such a Cu interconnection includes a dual damascene method and a single damascene method. In the dual damascene method, a via and a groove in an interconnection portion are formed by dry etching. Then, a barrier metal and a Cu seed film are formed, and a Cu film is formed by electrolytic plating. Thereafter, the quality of the Cu film is stabilized by heat treatment, and a Cu interconnection is formed by CMP (Chemical Mechanical Polishing).

On the other hand, in the single damascene method, first, a via is formed. Then, a barrier metal and a Cu seed film are formed, and a Cu film is formed by electrolytic plating. Thereafter, the quality of the Cu film is stabilized by heat treatment, and only the via is filled with the Cu film by CMP. Thereafter, an interlayer insulating film is formed, and an interconnection groove is formed by photolithography and dry etching. Then, the barrier metal and the Cu seed film are formed, and the Cu film is formed by electrolytic plating. After the quality of the Cu film is stabilized by heat treatment, only the interconnection groove is filled with the Cu film by metal CMP.

Cu plating is usually used in those two methods, however, it is known that the Cu plated film includes a large number of microvoids therein. In addition, it is considered that the voids are diffused in the film due to thermal stress, and are concentrated in an area under the via, if a stress migration test is conducted under a condition of 100° C. to 250° C. In particular, when an interconnection under a via has a large width, that is, a width not smaller than 1 μm, a defect tends to occur. If voids are concentrated in such a manner, a defect such as an increase in a via resistance, an open state, an increase in interconnection resistance, or disconnection may take place.

### SUMMARY OF THE INVENTION

The present invention was made to solve the above-described problems. An object of the present invention is to provide an interconnection structure suppressing concentration of voids in an interconnection under a via due to stress migration.

An interconnection structure according to one aspect of the present invention includes a first conductive layer, an insulating layer, a second conductive layer, and a barrier metal layer. The first conductive layer is formed on a substrate, and composed of a copper layer. The insulating layer is formed on the first conductive layer, and has a hole reaching the first conductive layer. The second conductive layer is formed within the insulating layer, and composed of a copper layer electrically connected to the first conductive layer through the hole. The barrier metal layer is formed between the second conductive layer and the hole, and the insulating layer. The barrier metal layer has an opening in a bottom portion of the hole, and the second conductive layer comes in direct contact with the first conductive layer through the opening.

In the interconnection structure according to one aspect of the present invention, the first conductive layer and the second conductive layer are in direct contact with each other through the opening provided in the barrier metal layer in the bottom portion of the hole. The first conductive layer and the second conductive layer are both copper layers. In other words, connection between the first conductive layer and the second conductive layer is established between metals of the same type. Therefore, concentration of voids under the hole due to connection between different metals, caused when a barrier metal is interposed between the first conductive layer and the second conductive layer, can be suppressed.

An interconnection structure according to another aspect of the present invention includes a first interconnection portion, a second interconnection portion, an insulating layer, and a conductive layer. The first interconnection portion is formed on a substrate. The second interconnection portion is formed on the substrate, and has a line width larger than that of the first interconnection portion. The insulating layer is formed on the first and second interconnection portions, and has a hole reaching the second interconnection portion. The conductive layer is electrically connected to the second interconnection portion through the hole, and formed within the insulating layer. The first interconnection portion is composed of a copper layer formed by plating. The second interconnection portion has a two-layered structure of a copper layer and a metal layer, which is positioned at least in a region directly under the hole.

In the interconnection structure according to another aspect of the present invention, the second interconnection portion connected to the hole has a two-layered structure of the copper layer and the metal layer, which is connected to the hole. Thus, as a portion connected to the hole is not a copper layer including a large number of microvoids, concentration of voids in an area under the hole due to stress migration can be suppressed.

In addition, as the first interconnection portion is composed only of the copper layer, interconnection resistance in the first interconnection portion with a small line width can be maintained to a low level, and deterioration of performance due to an increase in resistance will not occur.

An interconnection structure according to yet another aspect of the present invention includes a first conductive layer, an insulating layer, and a second conductive layer. The first conductive layer is formed on a substrate, and composed of a copper layer. The insulating layer is formed on the first conductive layer, and has a hole reaching the first conductive layer. The second conductive layer is formed within the insulating layer, and electrically connected to the first conductive layer through the hole. A slit is formed in the vicinity of the hole of the first conductive layer.

In the interconnection structure according to yet another aspect of the present invention, the slit is formed in the vicinity of the hole. Therefore, the slit serves as a wall when microvoids in the first conductive layer concentrate in a portion connected to the hole. Thus, since the microvoids cannot reach an area under the hole without going around the slit serving as the wall, concentration of microvoids in the area under the hole due to stress migration can be suppressed.

An interconnection structure according to yet another aspect of the present invention includes a first conductive layer, an insulating layer, and a second conductive layer. The first conductive layer is formed on a substrate, and composed of a copper layer. The insulating layer is formed on the first conductive layer, and has a first hole and a second hole reaching the first conductive layer. The second conductive layer for establishing electrical connection to another element is electrically connected. to the first conductive layer through the first hole, and formed within the insulating layer. The second hole is used as a dummy hole which does not electrically connect the first conductive layer to another element.

In the interconnection structure according to yet another aspect of the present invention, a dummy hole is provided in addition to the first hole for connecting the first conductive layer to the second conductive layer. Therefore, microvoids in the first conductive layer do not concentrate solely in the first hole, but are distributed to the first hole and the second, dummy hole. Thus, concentration of microvoids in the area under the first hole due to stress migration can be suppressed.

An interconnection structure according to yet another aspect of the present invention includes a first conductive layer, an insulating layer, and a second conductive layer. The first conductive layer is formed on a substrate, has a first interconnection portion with a large line width and a second interconnection portion with a small line width, and is composed of a copper layer. The insulating layer is formed on the first conductive layer, and has a hole reaching the second interconnection portion with a small line width. The second conductive layer is electrically connected to the first conductive layer through the hole, and formed within the insulating layer. The second interconnection portion with a small line width is bent between a junction of the second interconnection portion and the first interconnection portion, and the hole.

In the interconnection structure according to yet another aspect of the present invention, a bend portion is disposed between a connection portion of the second interconnection portion and the first interconnection portion, and the hole. Therefore, a large number of microvoids within the first interconnection portion with a large line width are less likely to reach an area under the hole. Thus, concentration of voids in the area under the hole due to stress migration can be suppressed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a configuration of a semiconductor device in Embodiment 1 of the present invention.

FIGS. 2 and 3 are schematic cross-sectional views illustrating, in the order of process steps, a first method of manufacturing a semiconductor device in Embodiment 1 of the present invention.

FIGS. 4 to 7 are schematic cross-sectional views illustrating, in the order of process steps, a second method of manufacturing a semiconductor device in Embodiment 1 of the present invention.

FIG. 8 is a schematic cross-sectional view showing a configuration of a semiconductor device in Embodiment 2 of the present invention.

FIG. 9 is a schematic cross-sectional view illustrating a method of manufacturing a semiconductor device in Embodiment 2 of the present invention.

FIG. 10 is a schematic plan view showing a configuration of a semiconductor device in Embodiment 3 of the present invention.

FIG. 11 is a schematic cross-sectional view along the line XI-XI in FIG. 10.

FIG. 12 is a schematic plan view showing another configuration of the semiconductor device in Embodiment 3 of the present invention.

FIGS. 13 and 14 are schematic plan views showing yet other configurations of the semiconductor device in Embodiment 3 of the present invention.

FIG. 15 is a schematic plan view showing a configuration of a semiconductor device in Embodiment 4 of the present invention.

FIG. 16 is a schematic cross-sectional view along the line XVI-XVI in FIG. 15.

FIG. 17 is a schematic plan view showing another configuration of the semiconductor device in Embodiment 4 of the present invention.

FIGS. 18 to 20 are schematic plan views showing yet other configurations of the semiconductor device in Embodiment 4 of the present invention.

FIG. 21 is a schematic plan view showing a configuration in which a dummy interconnection is provided in the semiconductor device in Embodiment 4 of the present invention.

FIG. 22 is a schematic cross-sectional view along the line XXII-XXII in FIG. 21.

FIG. 23 is a schematic plan view showing a configuration of a semiconductor device in Embodiment 5 of the present invention.

FIG. 24 is a schematic plan view showing another configuration of the semiconductor device in Embodiment 5 of the present invention.

FIG. 25 is a schematic plan view showing a configuration of a semiconductor device in Embodiment 6 of the present invention.

FIG. 26 is a schematic plan view showing a configuration of a semiconductor device in Embodiment 7 of the present invention.

FIG. 27 is a schematic plan view showing another configuration of the semiconductor device in Embodiment 7 of the present invention.

### DESCRIPTION OF THE PREFERRED EMBODIMENTS

In the following, embodiments of the present invention will be described with reference to the figures.

### Embodiment 1

Referring to FIG. 1, an interlayer insulating layer 1 is formed on a semiconductor substrate (not shown). A groove 1a is formed on the surface of interlayer insulating layer 1. A barrier metal layer 2 is formed along an inner wall of groove 1a, and an interconnection layer (a first conductive layer) 3 composed of a copper layer is formed so as to fill groove 1a.

An interlayer insulating layer 4 is formed on interconnection layer 3, and a via (hole) 4a reaching interconnection layer 3 and a groove 4b are formed in interlayer insulating layer 4. Via 4a is formed in a bottom portion of groove 4b. A barrier metal layer 5 is formed along the wall surface of via 4a and groove 4b. An interconnection layer (a second conductive layer) 6 composed of a copper layer is formed so as to fill via 4a and groove 4b, and so as to electrically connect to interconnection layer 3 through via 4a. Interconnection layer 6 is thus formed in interlayer insulating layer 4.

Barrier metal layer 5 described above has an opening in the bottom portion of via 4a, and interconnection layer 6 is in direct contact with interconnection layer 3 through that opening. An insulating layer 7 is formed on interlayer insulating layer 4 so as to cover interconnection layer 6.

Here, barrier metal layer 2, 5 is of a single-layer structure consisting of any of tantalum (Ta), tantalum nitride (TaN), titanium (Ti), titanium nitride (TiN), and tungsten nitride (WN), for example, or of a multi-layered structure consisting of any combination of such materials.

Next, two manufacturing methods in the present embodiment will be described.

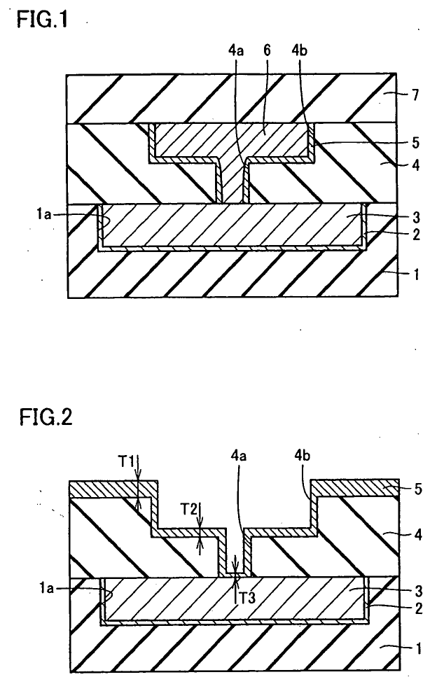

Referring to FIG. 2, interlayer insulating layer 1 is formed on the semiconductor substrate (not shown). Groove 1a is formed in interlayer insulating layer 1. Barrier metal layer 2 is formed on the entire surface of interlayer insulating layer 1 where groove la is formed, and thereafter, copper layer 3 is formed so as to fill groove 1a. Copper layer 3 is formed, by forming a copper seed layer followed by forming a copper plated layer by plating. Then, barrier metal layer 2 and copper layer 3 are polished and removed by CMP until the surface of interlayer insulating layer 1 is exposed. Thus, barrier metal layer 2 and copper layer 3 are left only in groove 1a, to form interconnection layer 3 composed of a copper plated layer (a copper layer formed by plating).

Interlayer insulating layer 4 is formed on interlayer insulating layer 1 so as to cover interconnection layer 3. Via 4a and groove 4b are formed on the surface of interlayer insulating layer 4 by dry etching. Via 4a is formed so as to extend from the bottom portion of groove 4b and to expose the surface of interconnection layer 3.

Barrier metal layer 5 is formed on the surface of interlayer insulating layer 4 where via 4a and groove 4b are formed, for example, by sputtering. When barrier metal layer 5 is formed by sputtering, film thickness of barrier metal layer 5 attains a relation of T1>T2>T3, due to a difference in the aspect ratio (depth/bottom size) of the opening. In other words, film thickness T1 of barrier metal layer 5 on the upper surface of interlayer insulating layer 4 is larger than film thickness T2 in the bottom portion of groove 4b, while film thickness T2 in the bottom portion of groove 4b is larger than film thickness T3 in the bottom portion of via 4a. Thereafter, the whole surface of barrier metal layer 5 is subjected to dry etching.

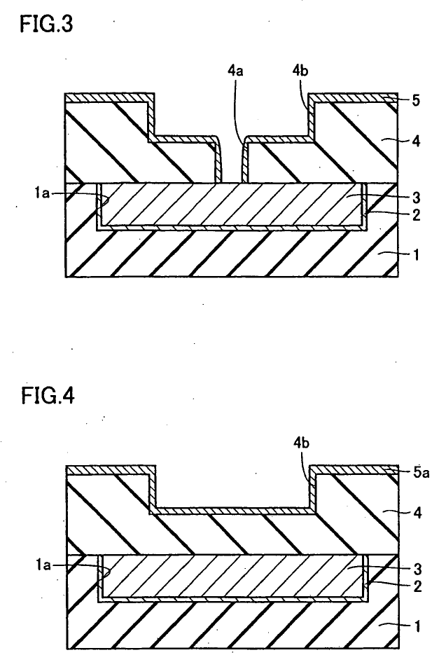

Referring to FIG. 3, film thickness of barrier metal layer 5 is smaller in the bottom portion of via 4a. Therefore, barrier metal layer 5 in the bottom portion of via 4a is removed by dry etching described above. Thus, an opening is formed in barrier metal layer 5 in the bottom portion of via 4a, and the surface of interconnection layer 3 is exposed through the opening.

Referring to FIG. 1, copper layer 6 is formed so as to fill via 4a and groove 4b. Copper layer 6 is formed, by forming a copper seed layer followed by forming a copper plated layer by plating. Then, barrier metal layer 5 and copper layer 6 are polished and removed by CMP until the surface of interlayer insulating layer 4 is exposed. Thus, barrier metal layer 5 and copper layer 6 are left only in via 4a and groove 4b, to form interconnection layer 6 composed of a copper plated layer. Thereafter, insulating layer 7 is formed on interlayer insulating layer 4 so as to cover interconnection layer 6.

Referring to FIG. 4, interlayer insulating layer 1, groove la, barrier metal layer 2, and interconnection layer 3 are formed in a manner similar to the first manufacturing method as described above.

Interlayer insulating layer 4 is formed on interlayer insulating layer 1 so as to cover interconnection layer 3. Groove 4b is formed on the surface of interlayer insulating layer 4 by dry etching. A barrier metal layer 5a is formed on the surface of interlayer insulating layer 4 where groove 4b is formed, for example, by sputtering.

Referring to FIG. 5, a resist pattern is formed on barrier metal layer 5a by photolithography. Thereafter, using the resist pattern as a mask, barrier metal layer 5a and interlayer insulating layer 4 are selectively removed by dry etching. Via 4a is thus formed in the bottom portion of groove 4b, and the surface of interconnection layer 3 is exposed on the bottom portion of via 4a. After the dry etching, the resist pattern is removed, for example, by ashing.

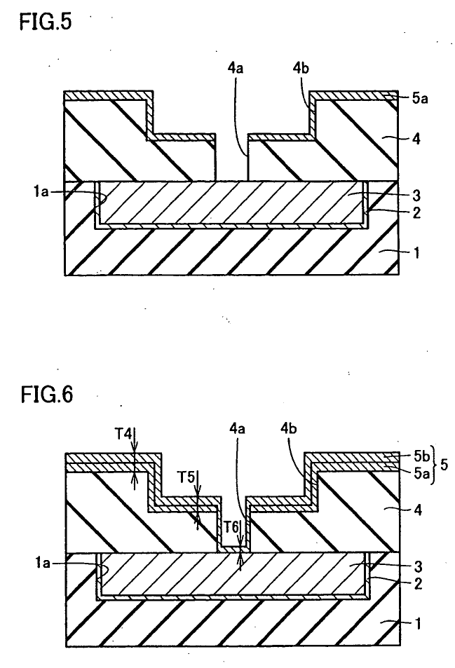

Referring to FIG. 6, a barrier metal layer 5b is formed on via 4a and barrier metal layer 5a. Film thickness of barrier metal layer 5 attains a relation of T4, T5>T6. In other words, barrier metal layers 5a and 5b are both formed on the upper surface of interlayer insulating layer 4 and on the bottom portion of groove 4b, while only barrier metal layer 5b is provided in the bottom portion of via 4a. Therefore, film thickness T4, T5 of barrier metal layer 5 on the upper surface of interlayer insulating layer 4 and on the bottom portion of groove 4b is larger than film thickness T6 of barrier metal layer 5 in the bottom portion of via 4a. Thereafter, the whole surface of barrier metal layer 5 is subjected to dry etching.

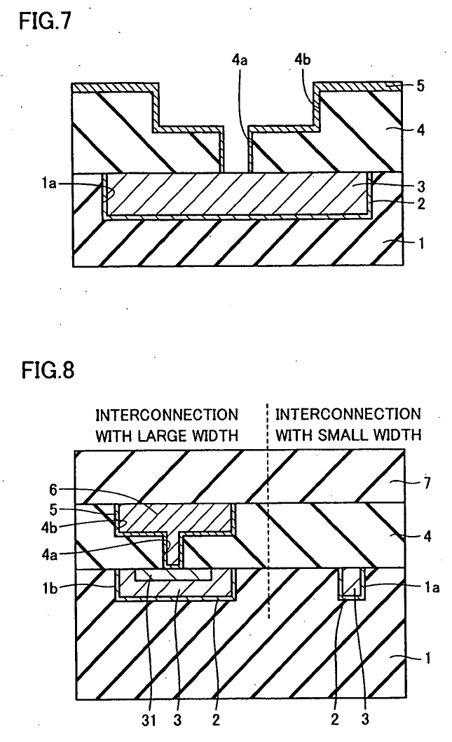

Referring to FIG. 7, film thickness of barrier metal layer 5 is smaller in the bottom portion of via 4a. Therefore, barrier metal layer 5 in the bottom portion of via 4a is removed by dry etching described above. Thus, an opening is formed in barrier metal layer 5 in the bottom portion of via 4a, and the surface of interconnection layer 3 is exposed through the opening.

Referring to FIG. 1, copper layer 6 is formed so as to fill via 4a and groove 4b. Copper layer 6 is formed, by forming a copper seed layer followed by forming a copper plated layer by plating. Then, barrier metal layer 5 and copper layer 6 are polished and removed by CMP until the surface of interlayer insulating layer 4 is exposed. Thus, barrier metal layer 5 and copper layer 6 are left only in via 4a and groove 4b, to form interconnection layer 6 composed of a copper layer. Thereafter, insulating layer 7 is formed on interlayer insulating layer 4 so as to cover interconnection layer 6.

According to the present embodiment, interconnection layer 3 and interconnection layer 6 are in direct contact with each other through the opening provided in barrier metal layer 5 in the bottom portion of via 4a, as shown in FIG. 1. Interconnection layer 3 and interconnection layer 6 are both copper layers. In other words, connection between interconnection layer 3 and interconnection layer 6 is established between metals of the same type. Therefore, concentration of microvoids under via 4a due to connection between different metals, caused when barrier metal layer 5 is interposed between interconnection layer 3 and interconnection layer 6, can be suppressed.

Unlike a conventional example, barrier metal layer 5 is not in contact with interconnection layer 3 on the entire bottom of via 4a, though it is in contact with interconnection layer 3 in a peripheral portion of the bottom portion of via 4a. Therefore, in the present embodiment, voids will not diffuse as far as a central area of the bottom portion of via 4a, and stress distribution can be made smaller. Thus, as described above, concentration of microvoids under via 4a can be suppressed, compared to the conventional example.

### Embodiment 2

Referring to FIG. 8, interlayer insulating layer 1 is formed on the semiconductor substrate (not shown). Groove 1a for an interconnection with a small line width (narrow interconnection) and a groove 1b for an interconnection with a large line width (wide interconnection) are formed on the surface of interlayer insulating layer 1. Barrier metal layer 2 is formed along each inner wall of grooves 1a, 1b. Interconnection layer (a first interconnection portion) 3 with a small width, composed of a copper layer formed by plating, is formed so as to fill groove 1a. In addition, an interconnection layer (a second interconnection portion) with a large width, having a two-layered structure of copper layer 3 formed by plating and a metal layer 31 is formed so as to fill groove 1b. The interconnection layer with a large width has a line width larger than that of the interconnection layer with a small width.

Interlayer insulating layer 4 is formed on interlayer insulating layer 1, so as to cover the interconnection layer with a small width and the interconnection layer with a large width. Via (hole) 4a reaching the interconnection layer with a large width and groove 4b are formed in interlayer insulating layer 4. Via 4a is formed in the bottom portion of groove 4b. Metal layer 31 of the interconnection layer with a large width is positioned at least in a region directly under via 4a, and comes in contact with barrier metal layer 5 in the bottom portion of via 4a.

Barrier metal layer 5 is formed along the wall surface of via 4a and groove 4b. Interconnection layer (a conductive layer) 6 composed of a Cu layer is formed so as to fill via 4a and groove 4b, and so as to electrically connect to the interconnection layer with a large width through via 4a. Interconnection layer 6 is thus formed in interlayer insulating layer 4. Insulating layer 7 is formed on interlayer insulating layer 4 so as to cover interconnection layer 6.

Here, metal layer 31 is a single-layer structure consisting of any of tantalum, tantalum nitride, titanium, titanium nitride, and tungsten nitride, for example; a multi-layered structure consisting of any combination of such materials; an aluminum alloy layer; or a copper layer formed by sputtering.

In addition, barrier metal layer 2, 5 is of a single-layer structure 30 consisting of any of tantalum, tantalum nitride, titanium, titanium nitride, and tungsten nitride, for example, or of a multi-layered structure consisting of any combination of such materials.

Next, a manufacturing method in the present embodiment will be described.

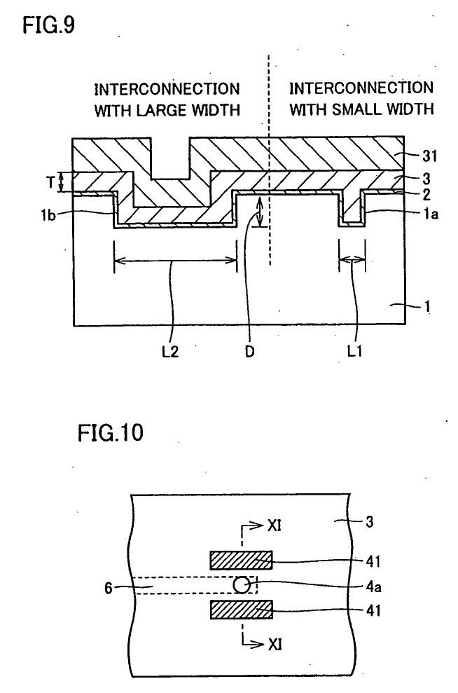

Referring to FIG. 9, interlayer insulating layer 1 is formed on the semiconductor substrate (not shown). Groove 1a for the interconnection with a small line width (narrow interconnection) and groove 1b for the interconnection with a large line width (wide interconnection) are formed in the interlayer insulating layer 1 by dry etching. Barrier metal layer 2 is formed on the entire surface of interlayer insulating layer 4 along each inner wall of grooves 1a, 1b. Copper layer 3 is formed on barrier metal layer 2. Copper layer 3 is formed, by forming a copper seed layer followed by forming a copper plated layer by plating. Metal layer 31 is formed on copper layer 3.

Here, copper layer 3 is formed to a film thickness so as to completely fill groove 1a, as well as to a film thickness so as not to completely fill groove 1b. More specifically, copper layer 3 is formed such that film thickness T is smaller than depth D of groove 1b, not smaller than half the dimension of width L1 of groove 1a (L1/2), and less than half the dimension of width L2 of groove 1b (L2/2). In other words, in order to completely fill groove 1a with copper layer 3, copper layer 3 should have film thickness T not smaller than L1/2. In order not to completely fill groove 1b with copper layer 3, copper layer 3 should have film thickness T smaller than depth D of groove 1b and less than L2/2.

Thereafter, metal layer 31 and copper layer 3 are polished and removed by CMP until the surface of interlayer insulating layer 1 is exposed. Thus, as shown in FIG. 8, only copper layer 3 is left in groove 1a, to form the interconnection layer with a small width, while both metal layer 31 and copper layer 3 are left in groove 1b, to form the interconnection layer with a large width.

Thereafter, interlayer insulating layer 4 is formed on interlayer insulating layer 1 so as to cover the interconnection layer with a small width and the interconnection layer with a large width. Via 4a and groove 4b are formed on the surface of interlayer insulating layer 4 and on the interconnection layer with a large width by dry etching. Via 4a is formed so as to extend from the bottom portion of groove 4b and so as to expose the surface of metal layer 31.

Barrier metal layer 5 is formed on the surface of interlayer insulating layer 4 where via 4a and groove 4b are formed, and copper layer 6 is formed so as to fill via 4a and groove 4b. Copper layer 6 is formed, by forming a copper seed layer followed by forming a copper plated layer by plating. Then, barrier metal layer 5 and copper layer 6 are polished and removed by CMP until the surface of interlayer insulating layer 4 is exposed. Thus, barrier metal layer 5 and copper layer 6 are left only in via 4a and groove 4b, to form interconnection layer 6 composed of a copper layer. Thereafter, insulating layer 7 is formed on interlayer insulating layer 4 so as to cover interconnection layer 6. According to this manufacturing method, the interconnection layer with a small width, composed of copper layer 3, and the interconnection layer with a large width, having a two-layered structure of metal layer 31 and copper layer 3, can easily be formed.

According to the present embodiment, the interconnection layer with a large width connected to via 4a has a two-layered structure of copper layer 3 and metal layer 31, to which via 4a is connected. Thus, as a portion connected to via 4a is not a copper plated layer including a large number of microvoids, concentration of voids in an area under via 4a due to stress migration can be suppressed.

In addition, as the interconnection layer with a small width can be composed only of copper layer 3, interconnection resistance in the interconnection layer with a small width can be maintained to a low level, and deterioration of performance due to an increase in resistance will not occur.

Here, though junction between metal layer 31 and copper layer 3 is established between metals of a different type, a contact area of metal layer 31 and the copper layer can readily be increased. Therefore, by increasing the contact area, local concentration of microvoids present in copper layer 3 in the junction between different metals can be suppressed.

Though FIG. 8 shows a configuration formed with the dual damascene method, the present embodiment can also be adapted to a semiconductor device formed with the single damascene method.

Further, even if a copper layer formed by sputtering is employed as metal layer 31, an effect as described above can be attained, because the copper layer formed by sputtering has the smaller number of microvoids than the copper layer formed by plating. It is to be noted that the copper layer formed by plating includes a large amount of impurity, such as chlorine (Cl), carbon (C), sulfur (S), or the like, contained in a chemical.

### Embodiment 3

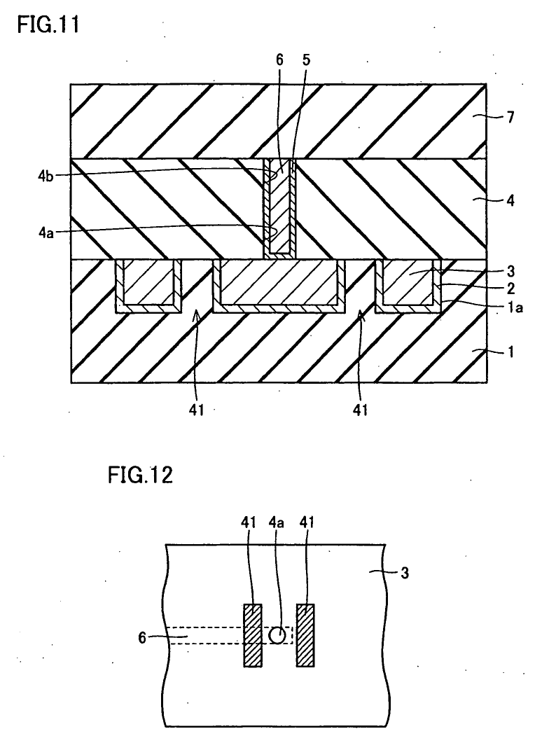

Referring to FIGS. 10 and 11, a configuration in the present embodiment is different from that in Embodiment 1 primarily in that a slit 41 is provided in interconnection layer (first conductive layer) 3 instead of forming an opening in barrier metal layer 5 in the bottom portion of via 4a.

Accordingly, barrier metal layer 5 is in contact with interconnection layer 3 on the entire surface of the bottom portion of via 4a. Slit 41 represents a region where groove la is not formed in interconnection layer 3 with a large width, and where interlayer insulating film 1 still remains, as shown in FIG. 11. For example, two such slits 41 are formed in the vicinity of via 4a, so as to interpose a portion connected to via 4a.

Configuration is otherwise approximately the same as that in Embodiment 1 described above. Therefore, same reference characters refer to same components, and description therefor will not be repeated.

According to the present embodiment, slit 41 is formed so as to interpose the portion connected to via 4a. Therefore, slit 41 serves as a wall when microvoids in interconnection layer 3 concentrate in the portion connected to via 4a. Thus, since the microvoids cannot reach an area under via 4a without going around the slit serving as the wall, concentration of microvoids in the area under via 4a due to stress migration can be suppressed.

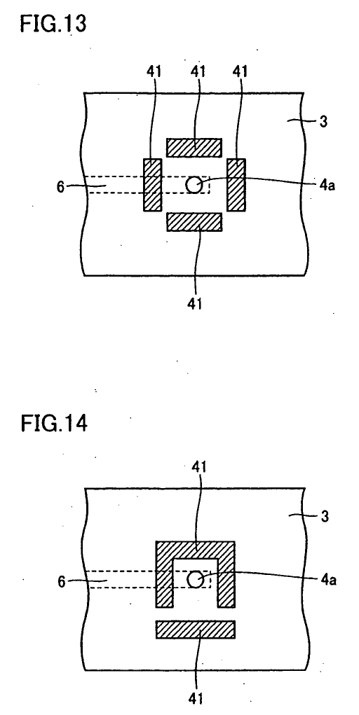

Though an example in which slit 41 is formed so as to extend in a direction the same as interconnection layer 6 (horizontal direction in the figure) has been described with reference to FIG. 10, it is to be noted that slit 41 may extend in a direction intersecting interconnection layer 6 Longitudinal direction in the figure, for example), as shown in FIG. 12. In addition, slit 41 may be provided so as to surround four sides around the portion connected to via 4a, as shown in FIG. 13. Further, slit 41 may be implemented by slit 41 in an inverted U shape surrounding three sides around the portion connected to via 4a, and by straight slit 41 arranged on remaining one side, as shown in FIG. 14.

### Embodiment 4

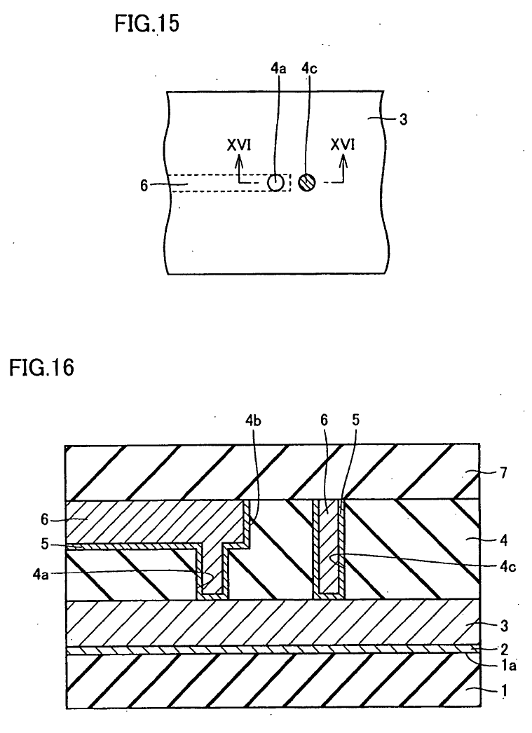

Referring to FIGS. 15 and 16, a configuration in the present embodiment is different from that in Embodiment 1 primarily in that a dummy via (dummy hole) 4c is provided in interlayer insulating layer 4 instead of forming an opening in barrier metal layer 5 in the bottom portion of via 4a.

Accordingly, barrier metal layer 5 is in contact with interconnection layer 3 on the entire surface of the bottom portion of via 4a. In addition, dummy via 4c does not electrically connect interconnection layer 3 to another element. Barrier metal layer 5 is formed along the inner wall of dummy via 4c, and copper layer 6 is formed so as to fill dummy via 4c. Copper layer 6 is not electrically connected to other interconnection layer other than interconnection layer 3.

Configuration is otherwise approximately the same as that in Embodiment 1 described above. Therefore, same reference characters refer to same components, and description therefor will not be repeated.

According to the present embodiment, dummy via 4c is provided in addition to via 4a for connecting interconnection layer 3 to interconnection layer 6. Therefore, microvoids in interconnection layer 3 do not concentrate solely in via 4a, but are distributed to a via 4a side and a dummy via 4c side. Thus, concentration of microvoids in the area under via 4a due to stress migration can be suppressed.

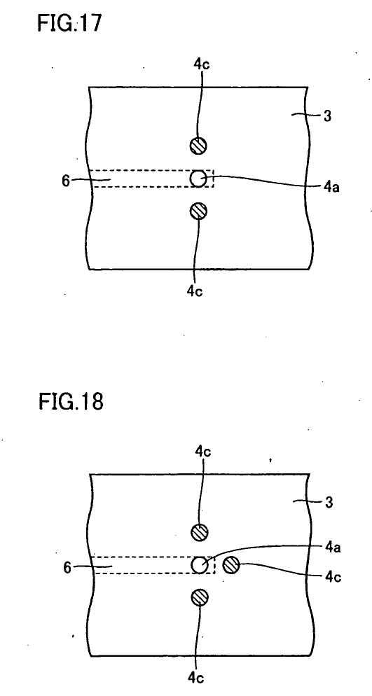

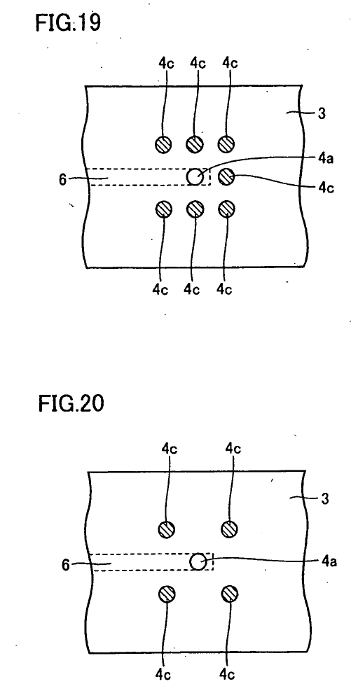

Though FIG. 15 shows a configuration in which one dummy via 4c is disposed, two or more dummy vias 4c may be provided, as shown in FIGS. 17 to 20. More specifically, two dummy vias 4c may be arranged so as to interpose via 4a, as shown in FIG. 17, or alternatively, three dummy vias 4c may be arranged so as to surround three sides around via 4a, as shown in FIG. 18. In addition, seven dummy vias 4c, for example, may be arranged so as to surround via 4a, as shown in FIG. 19, or alternatively, four dummy vias 4c may be arranged, as shown in FIG. 20.

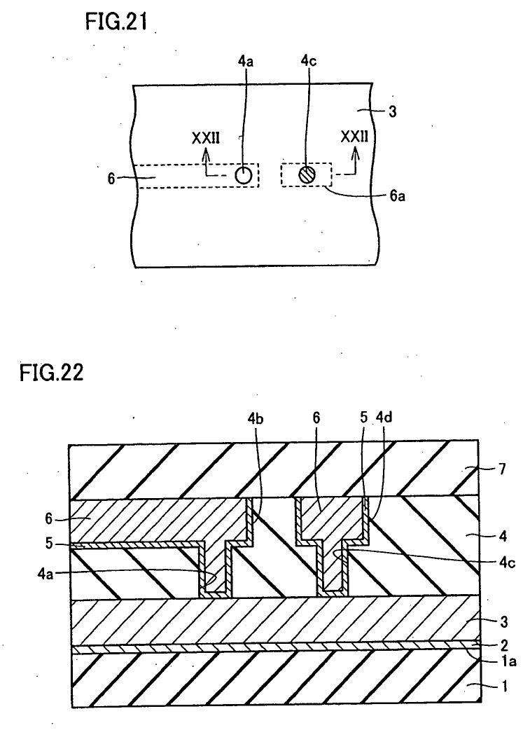

Dummy via 4c may electrically connect interconnection layer 3 to dummy interconnection layer 6, as shown in FIGS. 21 and 22. In such a case, a groove 4d for a dummy interconnection is formed on dummy via 4c of interlayer insulating layer 4. Barrier metal layer 5 is formed on the inner wall of dummy via 4c and groove 4d for the dummy interconnection, and dummy interconnection layer 6 composed of a copper layer is formed so as to fill dummy via 4c and groove 4d,for the dummy interconnection. Here, dummy interconnection layer 6 does not electrically connect interconnection layer 3 to another element.

Configuration is otherwise approximately the same as that shown in FIGS. 15 and 16 described above. Therefore, same reference characters refer to same components, and description therefor will not be repeated.

As described above, when dummy via 4c and dummy interconnection 6 are provided as well, an effect similar to that in FIGS. 15 and 16 can be attained.

### Embodiment 5

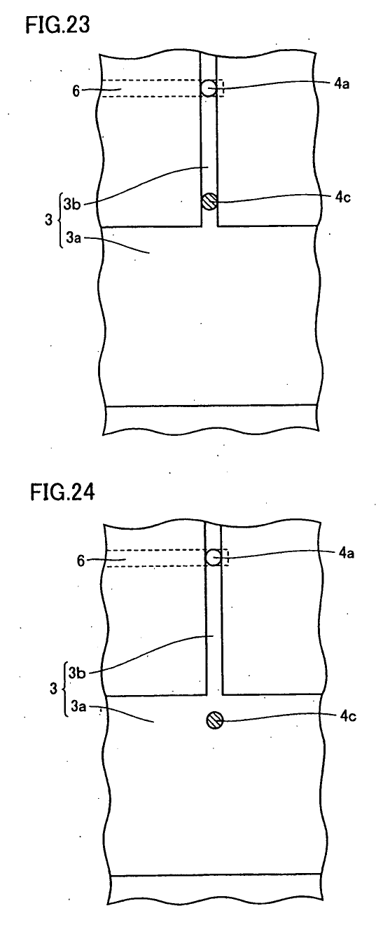

Referring to FIG. 23, a configuration in the present embodiment is different from that in Embodiment 4 primarily in a position where dummy via 4c is arranged.

Interconnection layer 3 includes an interconnection portion with a large line width 3a, and an interconnection portion with a small line width 3b. Interconnection layer 6 is electrically connected to interconnection portion with a small line width 3b of interconnection layer 3 through via 4a. Dummy via 4c is positioned on interconnection portion with a small line width 3b between a connection portion R of interconnection portion with a large line width 3a and interconnection portion with a small line width 3b, and via 4a.

Configuration is otherwise approximately the same as that in Embodiment 4 described above. Therefore, same reference characters refer to same components, and description therefor will not be repeated.

According to the present embodiment, dummy via 4c is provided in addition to via 4a for connecting interconnection layers 3 and 6. Therefore, microvoids in interconnection layer 3 do not concentrate only in via 4a, but are distributed to the via 4a side and the dummy via 4c side. Thus, concentration of voids in the area under via 4a due to stress migration can be suppressed.

A large number of microvoids in interconnection layer with a large line width 3a tend to concentrate in the area under dummy via 4c before reaching the area under via 4a. Therefore, concentration of voids in the area under via 4a can further be suppressed.

Even when dummy via 4c is arranged on interconnection layer with a large line width 3a as shown in FIG. 24, an effect as described above can be attained, so long as dummy via 4c is arranged in the vicinity of connection portion R of interconnection portion with a large line width 3a and interconnection portion with a small line width 3b.

In the present embodiment as well, the dummy interconnection layer may electrically be connected to interconnection layer 3 through dummy via 4c, or alternatively, the dummy interconnection layer does not need to be provided.

### Embodiment 6

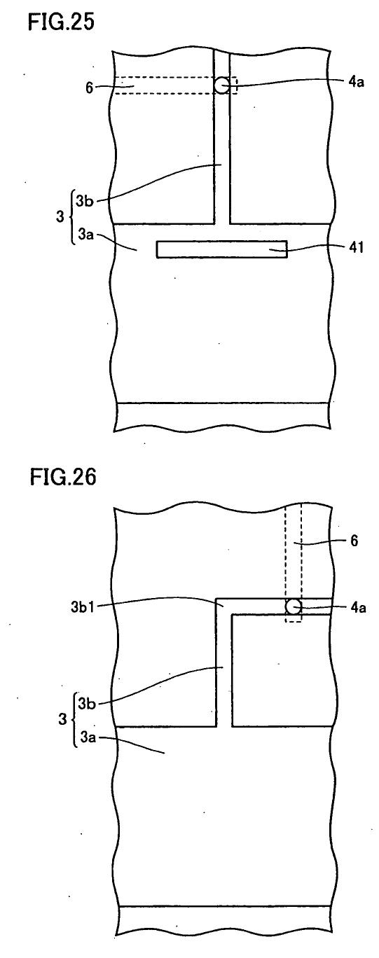

Referring to FIG. 25, a configuration in the present embodiment is different from that in Embodiment 3 in a position where slit 41 is arranged.

Interconnection layer 3 includes interconnection portion with a large line width 3a, and interconnection portion with a small line width 3b. Interconnection layer 6 is electrically connected to interconnection portion with a small line width 3b of interconnection layer 3 through via 4a. Slit 41 is positioned on interconnection portion with a large line width 3a in the vicinity of connection portion R of interconnection portion with a large line width 3a and interconnection portion with a small line width 3b.

Configuration is otherwise approximately the same as that in Embodiment 3 described above. Therefore, same reference characters refer to same components, and description therefor will not be repeated.

According to the present embodiment, slit 41 is formed in the vicinity of connection portion R. Therefore, a large number of microvoids in interconnection layer with a large line width 3a cannot reach an area under via 4a without going around slit 41 serving as the wall. Thus, concentration of voids in the area under via 4a due to stress migration can be suppressed.

### Embodiment 7

Referring to FIG. 26, a configuration in the present embodiment is different from that in Embodiment 5 in that interconnection portion with a small line width 3b is once bent at a bend portion 3b1 instead of providing a dummy via. Bend portion 3b 1 is arranged between connection portion R and via 4a.

Configuration is otherwise approximately the same as that in Embodiment 5 described above. Therefore, same reference characters refer to same components, and description therefor will not be repeated.

According to the present embodiment, bend portion 3b1 is disposed between connection portion R and via 4a. Therefore, a large number of microvoids within interconnection layer with a large line width 3a are less likely to reach an area under via 4a. Thus, concentration of voids in the area under via 4a due to stress migration can be suppressed.

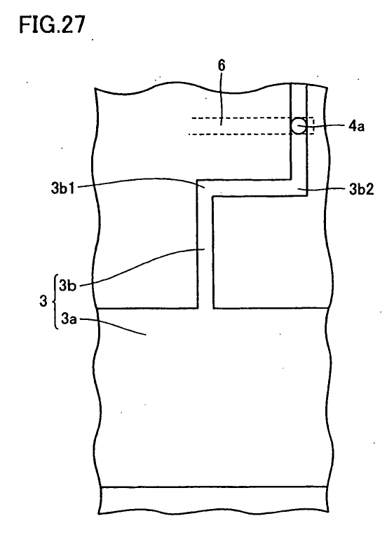

Though an example in which one bend portion 3b 1 is provided has been described above, two or more bend portions (two bend portions 3b1, 3b2, for example) may be arranged between connection portion R and via 4a, as shown in FIG. 27.

By arranging two or more bend portions, a large number of microvoids in interconnection layer with a large line width 3a are further less likely to reach the area under via 4a. Accordingly, concentration of voids in the area under via 4a due to stress migration can further be suppressed.

In the above-described embodiments, a copper layer represents a layer composed of a material consisting essentially of copper, and includes a layer composed of copper containing unavoidable impurities, a copper alloy layer, or the like.

The configurations in the above-described embodiments may be combined, as desired. In addition, though an interconnection structure for a semiconductor device has been described above, the present invention is widely applicable to an interconnection structure for an electronic device, such as a liquid crystal device, in addition to the semiconductor device.

Although the present invention has been described and illustrated in detail, it is clearly understood that the same is by way of illustration and example only and is not to be taken by way of limitation, the spirit and scope of the present invention being limited only by the terms of the appended claims.

1-9. (canceled)

10. An interconnection structure, comprising:
a first conductive layer formed on a substrate and composed of a copper layer;
an insulating layer formed on said first conductive layer and having a first hole and a second hole reaching said first conductive layer; and
a second conductive layer for electrical connection to another element, electrically connected to said first conductive layer through said first hole and formed within said insulating layer; wherein:
said second hole is used as a dummy hole which does not electrically connect said first conductive layer to another element;
said first conductive layer has a first interconnection portion with a large line width, and a second interconnection portion with a small line width;
said second conductive layer has a third interconnection portion;
said second interconnection portion with the small line width is connected to said third interconnection portion;
said second hole used as said dummy hole is formed so as to reach said first interconnection portion with the large line width.

11. An interconnection structure, comprising:
a first conductive layer formed on a substrate and composed of a copper layer;
an insulating layer formed on said first conductive layer and having a first hole and a second hole reaching said first conductive layer; and
a second conductive layer for electrical connection to another element, electrically connected to said first conductive layer through said first hole and formed within said insulating layer; wherein:
said second hole is used as a dummy hole which does not electrically connect said first conductive layer to another element;
said first conductive layer has a first interconnection portion with a large line width, and a second interconnection portion with a small line width;
said second conductive layer has a third interconnection portion;
said second interconnection portion with the small line width is connected to said third interconnection portion;
said second hole used as said dummy hole is formed so as to reach said second interconnection portion with the small line width; and
said second hole is positioned on said second interconnection portion with the small line width between a connection portion of said first interconnection portion with the large line width and said second interconnection portion with the small line width and said first hole.
